(19) United States
(12) Patent Application Publication
(10) Pub. No.: US 2009/0149035 A1
(43) Pub. Date: Jun. 11, 2009

(54) METHOD FOR MANUFACTURING OF A CRYSTAL OSCILLATOR

(76) Inventors: Sampo Aallos, Tampere (FI); Klaus Turhanen, Muijala (FI)

Correspondence Address: STITES & HARBISON PLLC, 1199 NORTH FAIRFAX STREET, SUITE 900, ALEXANDRIA, VA, 22314, US

(21) Appl. No.: 12/095,837

(22) PCT Filed: Dec. 1, 2006
(86) PCT No.: PCT/FI2006/000397

§ 371 Date: Sep. 24, 2008

(30) Foreign Application Priority Data
Dec. 1, 2005 (FI) 20051227

(51) Int. Cl. H01L 21/02

(52) U.S. Cl. 438/800; 257/E21.002

(57) ABSTRACT

A method of manufacturing a crystal oscillator, in which method semiconductor components and the crystal or another resonator (1) are joined to a bottom base (4), most suitably to the printed circuit board material. The components (2, 3, 5) are joined by soldering or gluing to said bottom base and the crystal and another resonator (1) are installed, in regard to other components (2, 3, 5), using the bottom base area on the same spot.

This invention relates to a method for manufacturing a crystal oscillator, in which method semiconductor components and the crystal or another resonator are joined to a bottom base, most suitably in the printed circuit board material and the components are joined by soldering or glued in said bottom base.

### Known Crystal Oscillators

### 1.1. Ceramic Structure

Previously known is the ceramic crystal oscillator structure, where the ceramic material includes a hole arrangement fitted or the oscillator, in other words cavity for the components. Furthermore, in the bottom of the cavity, in addition to the crystal, even other with the oscillator closely associated necessary components are joined, whereby the are at least partly screened. The crystal is joined either together or separately to the cavity. In this structure the encapsulated oscillator crystal can also be fixed on the cavity. In such a ceramic structure the case itself is an expensive component.

### 1.2. Cavity Carried Out by Printed Circuit Board Techniques

Also known is a space arranged for the component by printed circuit board techniques and which is made pressing the laminates, as circuit boards together, whereby there is in the other board a pre-made opening or openings, forming the cavities, that is the holes. The holes can also be made even after gluing, for instance by laser cutting, but it is a slow and expensive method. The disadvantage of gluing is that it spreads easily on a large area, also on the cavity bottom and reduces the area of location of components. In addition, the glue can spread out as a thin film on the bottom of cavity preventing fastening of components.

### 1.3 Manufacture of Crystal Oscillator Using Layered Conductive Material as Printed Circuit Board.

On the bottom base, which is of printed circuit board material or of other material suitable as composite base, the components are joined by soldering or gluing. In the periphery elevating bits of printed circuit board material or of homogeneously conducting material installed on the area of one oscillator. Crystal or another resonator is joined to the formed cavity by soldering or gluing. In this way the solution according to the publication of PCT/F101/01070 (Zipic Oy) is realised.

### 1.4 Manufacture of Crystal Oscillator Using Oscillator Crystal Packed on Printed Circuit Board.

In patent publication U.S. Pat. No. 6,160,458 manufacture of crystal oscillator using oscillator crystal packed on printed circuit board is known, whereby other components closely associated with it and the compensation circuits are situated in the near closeness of said crystal component and joined to it on the conductive connecting base. There is in the solution of the publication a conventional printed circuit board and in connection with the circuit board no cavity is formed for the components and nor is any component layering used in it.

### Manufacture of Crystal Oscillator Using Layered Component Structures

By means of the method according to the invention a new crystal oscillator model is achieved, the above presented problems are avoided and the manufacture of crystal oscillator module is made easier. In the invention no cavity is formed at all.

With this new method the oscillator is more profitable to manufacture than corresponding ceramic structures. The material and starting costs are lower. Testing of product is better. The oscillator can also be made smaller than the printed circuit board structures, for instance.

Characteristic of the method, where components are joined by soldering or gluing in the bottom base, is that the crystal or another resonator is installed, in regard to other components using the area on the same place, whereby on the bottom base one or several separate successive layers can be formed.

In the following the invention is disclosed with reference to the enclosed drawing, where

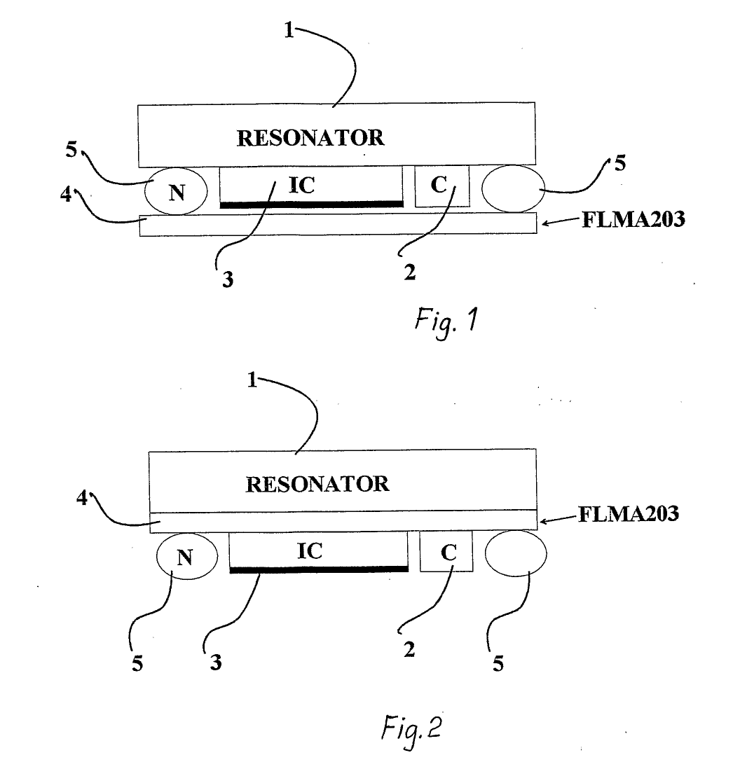

FIG. 1 shows a crystal oscillator manufactured with components one on top of another.

FIG. 2 shows a crystal oscillator with components one on top of another, but a bottom base between them.

FIG. 1 shows a manufacturing method of the crystal oscillator grammatically. On a bottom base 4 components 2, 3, 5 are placed by an electrically conductive joint, as by soldering or gluing. So the same area of bottom base 4 is utilized on placing the components when they are layered on the same side of the base 4.

FIG. 2 shows a crystal oscillator, where crystal or another resonator 1 is alone on the upper side of the base 4 and other components 2, 3, 5 on the under-side. Still the same area of the base 4 is utilized on both sides of the base. Here the fastening of the components takes place as in the solution in FIG. 1.

1. Method for manufacturing a crystal oscillator, in which method semiconductor components and the crystal or another resonator are joined to a bottom base, most suitably in the printed circuit board material and said components are joined by soldering or gluing in said bottom base, characterized in that the crystal or another resonator are installed in regard to said other components utilizing the area on the same place as the bottom base, whereby on said bottom base one or several separate layers can be formed one on top of another.

2. Method according to claim 1, characterized in that the components are on the bottom base, and the crystal and another resonator are installed on said components, for instance by means of an electrically conductive joint or by gluing.

3. Method according to claim 1 characterized in that the crystal or another resonator are installed on the upper side of the components and said components are placed under the bottom base.

4. Method according to claim 1, characterized in that the joint of the crystal oscillator to the next unit is made by means of bottom base.

5. Method according to claim 1, characterized in that there are in the bottom base one or several separate layers.
